(19) United States
(12) Patent Application Publication
(10) Pub. No.: US 2022/0120787 A1
(43) Pub. Date: Apr. 21, 2022

(54) DEVICE FOR HARNESSING WASTED POTENTIAL ENERGY

(71) Applicant: Ria M. PATEL, Lake City, FL (US)

(72) Inventor: Ria M. PATEL, Lake City, FL (US)

(21) Appl. No.: 17/378,172

(22) Filed: Jul. 16, 2021

Related U.S. Application Data
(60) Provisional application No. 63/093,805, filed on Oct. 20, 2020.

(51) Int. Cl. G01R 11/30; H02K 7/08; H02K 7/116; H02K 11/21; G01R 3/00; G01R 11/12

(52) U.S. Cl. CPC G01R 11/30; H02K 7/08; G01R 11/12; H02K 11/21; G01R 3/00; H02K 7/116

(57) ABSTRACT

An energy measuring device made of two same size blocks. The outline of two metal ball bearings are traced onto the blocks which are then drilled out where the tracings are marked. Ball bearings are inserted into the resulting holes. With the bearings fitted in place a dowel is inserted through the centers of the bearings to check out the fitting. The dowel is then removed and replaced with a roller. Next, a generator and gear assembly is fabricated comprising two gears and a band, the selected gears having a 10:1 ratio. A string is now loosely attached to the dowel so it can be wound up and released to measure an amount of energy created. The string is marked from 12-24 inches, in 6 inch increments, and these markings are used to control speed and turns for tests related to harnessing otherwise wasted energy.

### CROSS-REFERENCE TO RELATED APPLICATIONS

This application is based on U.S. provisional patent application 63/093,805 filed Oct. 20, 2020, the contents of which are incorporated herein by reference.

### STATEMENT REGARDING FEDERALLY SPONSORED RESEARCH OR DEVELOPMENT

Not Applicable.

### BACKGROUND OF THE INVENTION

The United States consumes about twenty-three percent of the entire world's energy but makes up only about 5 percent of the world's population (“50 Surprising Facts on Energy Consumption in America”, 2015). This shows how important electricity is as a commodity for the United States. Because of the strong presence of electricity in today's world, many researchers are dedicated to learning about energy conservation and how to obtain effective solutions to preserving energy consumption through renewable resources.

There are already several ideas on how to conserve electricity, some including kinetic energy, solar energy, and potential energy. Many of these forms of energy can be used to effectively conserve electricity due to their ability to use natural resources like water, wind, solar, or thermal energy.

Energy is what is used to do a specific type of work and energy is expressed in the units of Joules (J). The word energy comes from the Greek word “energia”, meaning activity. Forms of energy are divided into two categories; potential energy and kinetic energy.

Potential energy refers to stored energy. The different forms of potential energy include gravitational, chemical, nuclear, and elastic energy. Gravitational energy is when a mass or a large object moves away from the center of the Earth. The farther the object/mass moves away from the center of the Earth, the higher is the gravitational energy created between the two masses.

Chemical energy is the energy stored between atoms and compounds and is created when the connection between atoms and compounds is either created or broken.

Nuclear energy is created when the nucleus of an atom is split apart; This process is called fission. When atoms are broken apart they release large amounts of energy in two forms of kinetic energy. These are electromagnetic radiation and thermal energy (Morris, 2016).

Finally, elastic energy is energy that is mechanically stored in the form of a liquid, gas, spring or an elastic band. When stress is applied to the bonds between atoms in the elastic energy form, energy is created; but, when the stress is relaxed, energy is released.

Kinetic energy refers to energy developed through movement (Tinkler, 1970). The specific types of kinetic energy are motion, thermal energy and temperature, sound, electromagnetic radiation, and electromagnetic radiation. Motion energy is exactly how it sounds, any moving object can create kinetic energy. The object's mass and the square of its velocity are almost equivalent to the amount of kinetic energy created. If an object is dropped or a ball is thrown, kinetic energy is generated through motion.

Thermal energy is the difference between environmental temperature and systems inside of it. Between the environment and its subsystem thermal energy is created as heat. This can be compared to a hot cup of coffee. That is, the steam emitted through the surface of the coffee represents thermal energy that is then evaporated into the air.

Sound energy is created by vibrations. When an object vibrates and causes another object to vibrate too, the energy created is in the form of a liquid, solid, or gas.

Electromagnetic radiation is a form of something that can create energy which turns visible light into energy. Some forms of visible light are light bulbs and candles. Therefore, electric energy is created through the movement of electrons.

This also known as kinematics which is derived from the Greek word “kinema”, meaning movement (Anthony, 2013). Since kinetics are the science of motion, it means that simple activities like biking, walking, and running generate kinetic energy. There are five types of kinetic energy: radiant, thermal, sound, electrical/light, and mechanical/motion. This form of producing energy was first demonstrated by Gottfried Leibniz and Johann Bernoulli who dropped several weights from different heights into a block of clay to determine the correlation of depth and impact speed to height and weight (Hirschfelder & Dahler, 2009).

In biking, kinetic energy is taken from the speed of the bike and the movement of the wheels. This energy can be saved and converted to useable energy for various, different purposes.

Other examples of kinetic energy include airplanes in flight, waves crashing on a beach, an insect flying, someone skiing downhill, or an asteroid falling down to earth. Kinetic energy is now being used to create energy when, for example, people do the simple task of walking. Max Donelan, a biomedical physiologist at Simon Fraser University, created a brace which connects to a generator that attaches to a person's knee, allowing energy to be created from the person walking. Donelan says that one minute of walking with his invention can power a 30-minute cell phone call.

The popularity of kinetic energy is growing. Not only is kinetic energy easy to use, it is also a renewable and effective option. Researchers at Columbia University have started studying generating and using kinetic energy resulting from everyday activities.

Researchers and scientists believe that kinetic energy can impact the future. As new technological advances are appearing in the world, some are incorporating the ideas of kinetic energy into the architecture or building of it. The Polytechnic University of Milan, for example, is already using a technology called Lybra which is a rubber paving that converts the kinetic energy from vehicles moving on the roads and streets to electricity one can use (Anthony, 2013). Creative ideas like Lybra can lead to more innovative technological advancements.

Power is the rate of energy used over a certain time period when work is being done. To determine the amount of power associated with an activity, the equation used to calculate power is work divided by time. Work and time relate to energy amounts. Another formula for power is the force of energy multiplied by the velocity of energy. In scientific terms, power is measured in Watts (W) which equates to joules per second and the term is used to measure energy (Lukes, 2007). The term “Watt” was first established by a Scottish engineer, named James Scott, who experimented how to measure energy output and described his values in term Watts (Anthony, 2013). To create power, there must be some kind of physical work. The faster the work and speed, the more power generated. An example of how power works is two kids running a mile. The first kid is twice the mass of the second kid. They both run the same distance as the other. Both kids are also doing the same amount of running, but one of them is doing more work than the other. Even though the second kid is faster on the time element, the first kid has more power. This is because of the mass difference between the two children. Since the first kid has double the mass of the second kid, the first kid is doing double the work of the first kid who has half his mass.

Alternating Current (AC) and Direct Current (DC) describe the way an electric charge flows. DC has an electric charge that flows only in one direction whereas in AC the electric charge flow alternates flowing first in one direction and then in the opposite direction. An AC motor consists of a stator and a rotor. The rotor rotates inside a magnetic field. DC motors have a voltage induced rotating armature winding, and a non-rotating armature field frame winding that is a static field or permanent magnet. They also use different motor connections than normal ones so they can produce different amounts of speed and torque. They can be controlled, winding wise, by using a device to adjust the voltage levels. Overall, DC motors are better for controlling experiments; while AC motors are better off for producing single-phase power that is used for relatively longer periods of time.

Currently many products and devices use renewable energy sources, a few of these being things you might see every day. One, for example, is a windmill which uses a generator to create energy and is similar to what the device of the present invention is trying to do to produce renewable energy.

Wasted energy is energy that cannot be created or destroyed, but rather is a type of energy that can only be transferred from one form to another. An example of wasted energy is a lamp. An electric lamp produces heat energy and transfers this energy to its surroundings. In most instances one cannot do much with this energy and it all goes to waste; although, the device of the present invention might change that.

If we take the wasted energy from cars and other vehicles and use it correctly, then we may have found a way where wasted energy can be reused. This can be done because cars use energy to drive and then once it is used it may be described as wasted energy. Using the device of the present invention, now, one would use up the wasted energy by making energy at the same time, as described herein, by driving over rollers. That is, if rollers of some sort are placed in the ground and driven over continuously, one could set it up to create energy from the amount of rotations the rollers make. This new energy source could then be used to power up things like road signs or street lights which would help preserve more energy overall.

This present invention is designed to create a way to utilize wasted energy by doing an everyday routine task. Everyday, when people are driving their car, bike, or motorcycle, large amounts of energy is wasted. This current invention was developed to build on the basis of using a common activity as a means to use wasted energy. The idea is that if people are consistently putting energy into driving on roads, for example, then they could also generate energy as a second, beneficial use, of that everyday activity. To create potential energy by using a rotational roller as described herein, research was done on kinetic and potential energy and how to correctly use it with energy coming from physical motion. Based on the research and test trials, the innovative device of the present invention can be used to generate enough power to help improve the lives of others and provide power to devices within that user's vicinity.

### BRIEF SUMMARY OF THE INVENTION

This invention is directed to the harnessing of otherwise wasted potential energy by use of a rotational roller; and, in particular, for harvesting energy resulting from road conditions and traffic traversing over the roads.

For this purpose, the behavior of a generator, made as described hereinafter, is tested to determine the generator's overall design and how well it functions when the roller incorporated in the generator's construction operates. If the rotational spinning device is spun for longer periods of time, at the same speed, it should harness more energy because the more the generator is actively turning, the more energy it will create. The amount of energy the generator produces will continue to expand until the generator ceases operation.

Other objects and features will in part apparent and in part pointed out hereinafter.

### BRIEF DESCRIPTION OF THE DRAWING

In the drawings,

FIG. 1 is a simplified representation of the device of the present invention;

FIGS. 2-4 are graphs depicting data derived from different test performed using the device; and,

FIG. 6 is graph illustrating the average results from the various tests.

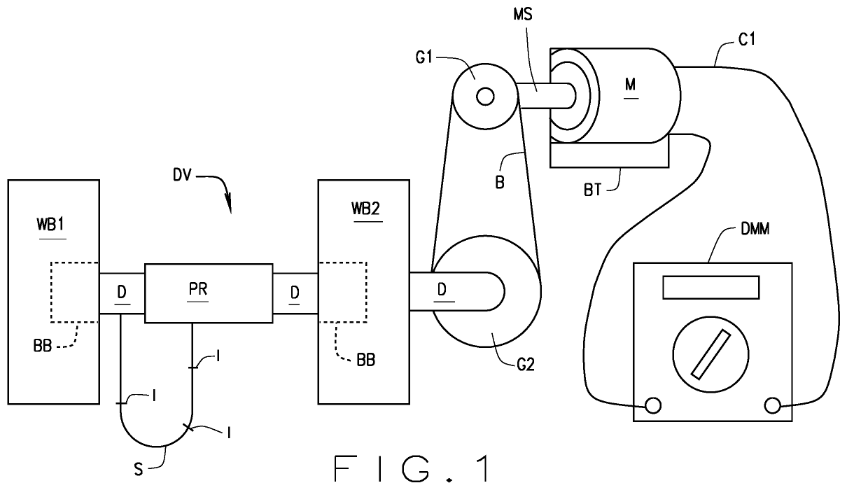

### DETAILED DESCRIPTION OF THE INVENTION

The following detailed description illustrates the claimed invention by way of example and not by way of limitation. This description will clearly enable one skilled in the art to make and use the claimed invention, and describes several embodiments, adaptations, variations, alternatives and uses of the claimed invention, including what I presently believe is the best mode of carrying out the claimed invention. Additionally, it is to be understood that the claimed invention is not limited in its application to the details of construction and the arrangements of components set forth in the following description or illustrated in the drawings. The claimed invention is capable of other embodiments and of being practiced or being carried out in various ways. Also, it is to be understood that the phraseology and terminology used herein is for the purpose of description and should not be regarded as limiting.

For purposes of this description, those skilled in the art will understand that:

Independent Variable: The number of turns tested per trial.

Dependent Variable: Measured Volts determined using a Voltmeter.

Controlled Variables: The same controlled speed is used for each test based on a controlled pull regardless of how many turns the roller makes, this being reconfirmed by use of a digital tachometer. Also, the same test setup and materials are used, dissipated the energy between trials, and tests were conducted on the same flat surface for each design.

### Materials Required

2 ball bearings

Hot glue gun

Drill

3 different colored pens

Scotch tape

A 12 inch wooden dowel that can fit through a middle hole of the ball bearings, this all depending on the size chosen for the particular design.

10 inch paint roller barrel with a ¼ inch diameter

Alligator Clips

Digital Multimeter

30 inches of String

Pulley Unit Set (gears and bands)

Pulley Unit Set (gears and bands)

Digital Meter Tachometer with sticker indicator

2 pieces of wood each being 1.5 inch by 9 inch by 3.5 inch

25 inch piece of string.

Scissors

Saw

Cardboard to prop up generator kit

### Procedures

1. First make the device DV on which to test the product by taking two wood blocks WB1, WB2.

2. Cut wood blocks WB1, Wb2 to a size of 1.5 inch by 9 inch by 3.5 inch. This is done using a saw.

3. Next put the wood blocks WB1, WB2 side-by-side and trace an outline of a ball bearing BB onto both sides of each piece of wood. Make sure the sizes are equal before drilling.

4. Once everything is measured properly, use a drill to cut two holes into which ball bearing BB will fit.

5. Using a hot glue gun, apply glue inside the respective holes that are created and place a ball bearing BB into each hole. Ensure everything is glued on and sturdy before continuing. Also make sure each ball bearing can spin freely.

6. Now take a paint roller PR and take everything off it where two holes are created at both ends for dowel D to slide through. Make sure the hole in the roller properly fits inside the wooden dowel.

7. Place paint roller PR onto wooden dowel D.

8. Now hot glue the roller onto the dowel.

9. Attach the dowel to the two ball bearings by sticking the dowel through the holes of the bearings.

10. Tie one end of a string S to an end of dowel D and the other end of the string to the roller.

11. Mark string S in increments I of 6 inches starting at 12 inches from the end of the string attached to dowel D up to 24 inches.

12. Next chose from the pulley set a first gear G1 and a second gear G2, the ratio between gears G1 and G2 being 10:1.

13. Attach the smaller gear G1 to a motor shaft MS of a motor M and secure the motor to a motor stand ST.

14. Now attach a belt B between gears G1 and G2 and so there is some tension on the belt.

15. Finally, attach larger gear G2 to an end of dowel D and align gears G1, G2; again, allowing enough distance between the gears so there is a tension on belt B running between them.

16. Set up digital multimeter DMM for use in recording test data when the dowel is spinning.

17. Attach electrical connectors C1, C2 such as those having alligator clips between motor M and multimeter DMM.

18. Set up multimeter DMM to act as a tachometer which measures motor speed during each trial.

19. Wrap string S on dowel D around the dowel at the first 12 inch mark and then pull the string using a controlled force.

20. Record the multimeter DMM measurements and the speed measured by the tachometer for each pull. Make sure the speeds produced are approximately the same for every trial. Do this 30 times.

21. Repeat steps 19 and 20, 30 times for all 3 different string lengths (12 inches, 18 inches, and 24 inches) and record the appropriate data.

### Results

Data taken at 4 revolutions per second (rps), based on the tachometer readings between each controlled pull for each set of 30 trials, is listed in the following chart.

| | 12 inch string (V) | 18 inch string (V) | 24 inch string (V) |
|---|---|---|---|
| 1 | 0.50 | 1.60 | 2.51 |
| 2 | 0.34 | 1.46 | 2.83 |
| 3 | 0.74 | 1.32 | 2.76 |
| 4 | 0.93 | 1.51 | 2.59 |
| 5 | 0.61 | 1.54 | 2.79 |
| 6 | 0.84 | 1.78 | 2.58 |
| 7 | 0.79 | 1.82 | 2.82 |
| 8 | 0.72 | 1.79 | 2.98 |
| 9 | 0.68 | 1.85 | 2.74 |
| 10 | 0.49 | 1.69 | 2.61 |
| 11 | 1.15 | 1.92 | 2.49 |
| 12 | 0.39 | 1.44 | 2.61 |
| 13 | 0.45 | 1.34 | 2.83 |
| 14 | 0.48 | 1.31 | 2.95 |
| 15 | 0.68 | 1.43 | 3.01 |
| 16 | 0.63 | 1.49 | 2.87 |
| 17 | 0.36 | 1.58 | 2.81 |
| 18 | 0.76 | 1.64 | 2.72 |
| 19 | 0.86 | 1.78 | 2.62 |
| 20 | 0.81 | 1.69 | 2.77 |
| 21 | 0.77 | 1.93 | 2.69 |
| 22 | 0.71 | 1.85 | 2.83 |
| 23 | 0.81 | 1.75 | 2.74 |
| 24 | 0.69 | 1.71 | 2.97 |
| 25 | 0.87 | 1.68 | 3.02 |
| 26 | 0.62 | 1.63 | 2.91 |
| 27 | 0.66 | 1.98 | 2.66 |
| 28 | 0.73 | 1.74 | 2.84 |
| 29 | 0.68 | 1.86 | 2.71 |
| 30 | 0.64 | 1.60 | 2.43 |

The average of the data from the 30 trials is:

| 12 inch string | 18 inch string | 24 inch string |
|---|---|---|
| 0.68 V | 1.66 V | 2.76 V |

The standard deviation of data from the 30 trials is:

| 12 inch string | 18 inch string | 24 inch string |
|---|---|---|
| 0.178 | 0.186 | 0.156 |

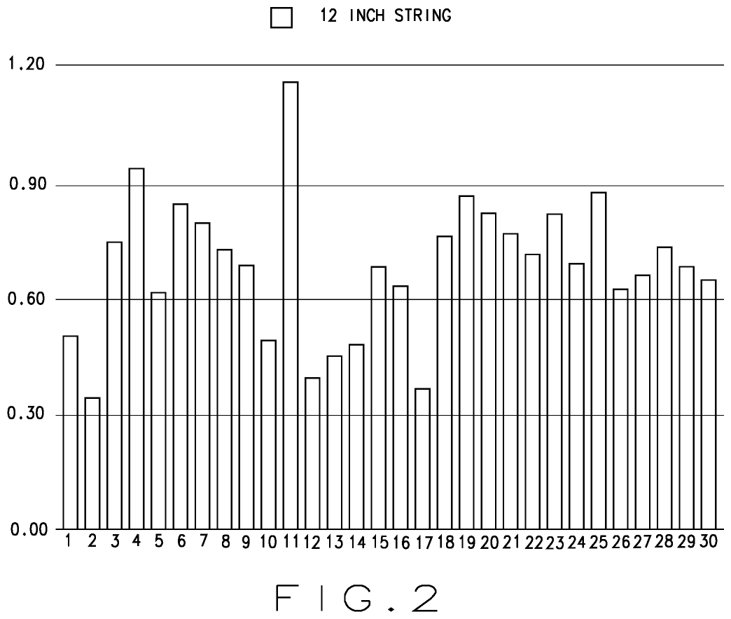

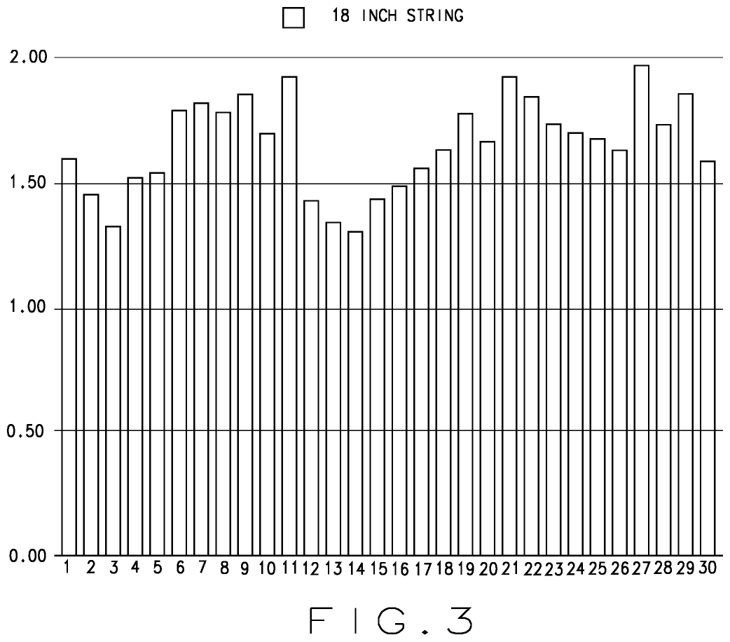

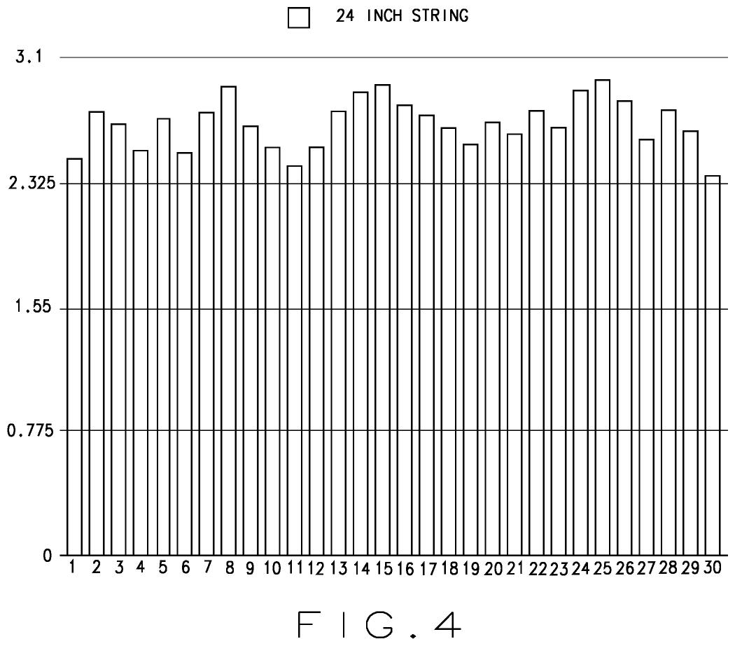

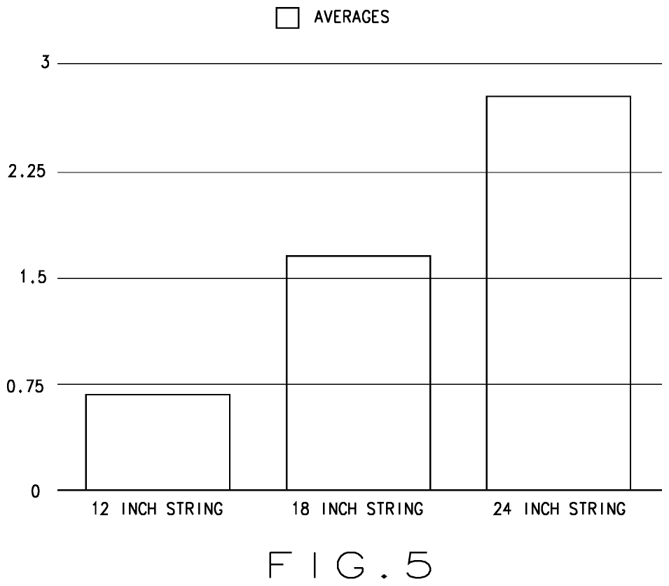

The graphs shown in FIGS. 2-5 each depict test results obtained using different lengths of string; i.e., a 12 inch string in FIG. 2, and 18 inch string in FIG. 3, and a 24 inch string in FIG. 4. Each graph lists the number of trials on the x-axis and the energy produced (in Volts) for the trials is represented on the y-axis.

Finally, FIG. 5 is a bar graph of the averages of the 30 trails for each length of string pulled. The longest, 24 inch string, by far produces the most energy because of how many more rotations it has. The shorter pull, represented by the 12 inch string, produces the least energy due to its significantly fewer rotations.

### Data Analysis

The results of this experiment demonstrate that using a device created to simulate a vehicle driving over a roller, more energy will be produced the longer the roller spins. The average amount of energy produced at the shortest distance of 12 inches was 0.68 V. The average amount of energy produced at the medium length of 18 inches was 1.66 V. Finally, the average amount of energy produced at the largest length of 24 inches was 2.76 V. This shows that more energy is generated if the roller is spun at longer times. In this case, the longer time is represented by the length of the markings on the string that each trial is to.

As set forth in the above graph, standard deviation of the results were 0.156, 0.178, and 0.186 for 24 inches, 12 inches, and 18 inches, respectively. The lower the standard deviation value is, the more accurate are the test results. Based on the results, the trials for 18 inches showed a slightly higher standard deviation. This result could be because the variation between trials was minimal resulting from the experiments being were carried out with controlled methods. That is, the test data was acquired with a digital tachometer to ensure the values being recorded accorded with the methods of testing. Any slight fluctuation in recording voltages could have resulted in any slight difference in the standard deviation.

Based on the results, the average amount of energy produced from each of these three distances increases as the distance and time increases. Friction of the ball bearings can play a huge factor on how many smooth revolutions can occur from the gears. The 10:1 ratio in the gears also helped generate more energy. Focusing on these aspects of the tests can help improve the performance and amount of energy that each rotation generates.

### Experimental Error

Applicant notes that a few different factors that could have affected the results of this experiment. One of these, for example, was that the dowel used was wooden. It will be appreciated that while the testing was done to prove a concept, use of a wooden dowel may slow down the speed of the roller versus use of a dowel made of another material (i.e., metal or plastic) if tested on a road. It would be best to test more durable but lighter options such as a hollow metal rod, or plastic rod. Other possible reasons for the roller not performing as expected could be related to a lack of straightness of the dowel and any friction resulting from use of a wooden dowel. In future tests, a straighter dowel will be used and material with friction will be tested.

During the tests, sometimes the belt would come off of the gears and the alignment would have to be straightened. To prevent this from occurring in other trials, a cardboard platform or the like can be used. Another factor that could have affected the results is the paint roller that was used. Such a roller may have added excess weight or drag onto the dowel making the dowel harder to spin. Better materials will need to be tested when working with rollers.

In terms of recording results, some errors occurred when the voltage would fluctuate so often that the peak voltage may not have been properly recorded. In the future tests this can be fixed by using a digital voltmeter connected to recording software. The more these trials are recorded, the more information will be collected. There are many imperfections that will need to be fixed in the prototype to allow for a more meaningful and effective product.

### CONCLUSION

In conclusion, the predicted hypothesis was supported by the testing. The prediction was that more energy will be produced if a generator spins for a longer period of time. This is true because the longer something is spun, the more times it will rotate, and if connected to a generator, produce energy. Another contributing factor to the amount of energy generated was the gear ratio used. If more gears or a larger gear ratio is used, the greater the number of turns made on the generator thereby producing more energy. This is something else to test out in the future.

Many things have been learned from the experiment whose purpose was to harness wasted potential energy from the use of a rotational roller coupled to an electrical generator. The underlying hypothesis was tested by making a device that could used in performing appropriate experiments.

In summary, the device was created by first using a saw to cut two wooden blocks to the same size. Then, the outline of two metal ball bearings was traced onto the blocks of wood. The wood was then drilled into where the tracings were marked. Inside of the resulting holes the bearings were hot glued and a wooden dowel was inserted through the centers of the bearings to check out the fitting. The wooden dowel was then removed and a paint roller was placed in the center of the dowel. Next, a motor and gears assembly was fabricated. For this purpose, a pulley unit kit was used and two gears and bands were chosen. The gears selected were of a 10:1 ratio. Finally, a string was loosely attached onto the wooden dowel so it could be tied up and released to test the energy amount. The string was marked from 12 to 24 inches in 6 inch increments and these markings were used to control the speed and turns for 30 trials.

The results of the experiment are that it is possible to harness wasted potential energy using a rotational roller. The longest string used during testing produced the greatest amount of energy, the medium string produced the second most amount of energy, and the shortest string produced the least amount of energy. This was as predicted. Importantly, the device created produced more energy than expected. As such, the high amounts of energy harnessed proved that this device and process could be an incredibly effective way of harnessing otherwise wasted potential energy. This experiment was designed to mimic of a car traversing a road. If this amount of energy produced was multiplied several times to effectively represent what would happen with a real, life size vehicle, then the amount of energy produced would be significant. There would be even more energy produced since traffic can be constant on a road. The implications of this project are vast and can prove to be very effective in generating great amounts renewable energy in the future.

In view of the above, it will be seen that the several objects and advantages of the present invention have been achieved and other advantageous results have been obtained.

As various changes could be made in the above constructions without departing from the scope of the invention, it is intended that all matter contained in the above description or shown in the accompanying drawings shall be interpreted as illustrative and not in a limiting sense.

### REFERENCES

50 Surprising Facts on Energy Consumption in America. (2017, May 23). Retrieved Oct. 1, 2017, from https://www.electricchoice.com/blog/50-surprising-facts-on-energy-consumption/
Anthony, S. (2013). Kinetic Energy Harvesting: Everyday Human Activity Could Power the Internet of Things. ExtremeTech, 11 Jul. 2013, www.extremetech.com/extreme/161079-kinetic-energy-harvesting-everyday-human-activity-could-power-the-internet-of-things.
Churchill, J. (1872). Laws of Electricity. Scientific American, 27(4), 52-52. Retrieved from http://www.jstor.org/stable/26054755
Hirschfelder, J., & Dahler, J. (2009). The Kinetic Energy of Relative Motion. Proceedings of the National Academy of Sciences of the United States of America, 42(6), 363-365. Retrieved from http://www.jstor.org/stable/89788
Lukes, S. (2007). Power. Contexts, 6(3), 59-61. Retrieved from http://www.jstor.org/stable/41801062
Morris, A. (2016). Energy. In Why Icebergs Float: Exploring Science in Everyday Life (pp. 137-142). London: UCL Press. Retrieved from http://www.jstor.org/stable/j.ctt1gxxpgr.19
MURPHEY, C. (2012). Electricity. The North American Review, 297(4), 35-39. Retrieved from http://www.jstor.org/stable/24414825
Tinkler, K. (1970). The Kinetic Energy of a Random Walk. Area, 2(1), 28-32. Retrieved from http://www.jstor.org/stable/20000401
Weiss, A., Larrabee, F., Bartis, J., & Sawak, C. (2012). Overview of Current Energy Issues. In Promoting International Energy Security: Volume 2, Turkey and the Caspian (pp. 9-18). Santa Monica, Calif.; Arlington, Va.; Pittsburgh, Pa.: RAND Corporation. Retrieved from www.jstor.org/stable/10.7249/j.ctt3fgzsb.11

1. An energy measuring device for testing the harvesting of energy resulting from the condition of roads over which vehicles travel and from traffic traversing over the roads comprising:
a generator;
an instrument for measuring an energy output of the generator;
two ball bearings;
two blocks of the same size onto each of which an outline of a ball bearing is traced, each of the blocks then being drilled out where the tracings are marked and one of the ball bearings being fitted into each of the resulting holes;
a dowel and a roller, the dowel first being inserted through centers of the ball bearings to check out each fitting, the dowel then being removed and replaced with the roller;
a gear assembly formed of two gears having a predetermined gear ratio and a band, one of the gears being connected to a generator shaft and the other gear to the roller with the band connecting the two gears; and,
a string of a predetermined length and which is marked at predetermined intervals, the string being loosely attached to the roller so to wind up the roller and measure an amount of energy created by the generator when the roller is released, the markings on the string being used to control the rotational speed of the generator for conducting tests related to harnessing otherwise wasted energy.

2. The energy measuring device of claim 1 in which the predetermined gear ratio is 10:1.

3. The energy measuring device of claim 1 in which the string is marked from 12 inches to 24 inches in 6 inch increments.

4. The energy measuring device of claim 1 in which the two blocks are wood blocks cut to the same size.

5. The energy measuring device of claim 1 in which the roller is a paint roller.

6. A method of fabricating an energy measuring device for testing the harvesting of energy resulting from the condition of roads over which vehicles travel and from traffic traversing over the roads and employing a generator and an instrument for measuring an energy output of the generator, the method comprising;
forming blocks into the same and shape;
tracing an outline of a ball bearing on each block size two ball bearings;
drilling out each block where the tracings are marked and inserting one of the ball bearings into each of the resulting holes in each block;
inserting a dowel through center a dowel and a roller, the dowel first being inserted through a center of each of the ball bearings to check out each fitting;
then removing the dowel and replacing the dowel with a roller;
forming a gear assembly using two gears having a predetermined gear ratio and a band, one of the gears being connected to a generator shaft and the other gear to the roller with the band connecting the two gears; and,
loosely attaching a string of a predetermined length and which is marked at predetermined intervals to the roller so to wind up the roller and measure an amount of energy created by the generator when the roller is released, the markings on the string being used to control the rotational speed of the generator for conducting tests related to harnessing otherwise wasted energy.

7. The method of claim 6 in which the predetermined gear ratio is 10:1.

8. The method of claim 6 in which the string is marked from 12 inches to 24 inches in 6 inch increments.

9. The method of claim 6 in which the two blocks are wood blocks cut to the same size.

10. The method of claim 6 in which the roller is a paint roller.
